(19) United States
(12) Patent Application Publication
(10) Pub. No.: US 2026/0223636 A1
(43) Pub. Date: Jul. 30, 2026

(54) MICRO-TRANSFER PRINTING WITH VERTICAL TETHERS

(71) Applicant: X-Celeprint Limited, Dublin (IE)

(72) Inventors: António José Marques Trindade, Cork (IE); Ronald S. Cok, Rochester, NY (US); Joao Barbosa, Dublin (IE)

(21) Appl. No.: 19/036,827

(22) Filed: Jan. 24, 2025

(51) Int. Cl. H01L 21/683; H01L 23/00

(52) U.S. Cl. CPC H10P 72/74; H10P 72/743; H10W 72/00

(57) ABSTRACT

A micro-transfer-printable component source structure includes a source wafer having sacrificial portions disposed on only a portion of a surface of the source wafer, a component disposed on and entirely over the sacrificial portion, and a vertical tether extending in an at least partially vertical direction orthogonal to the surface along a sacrificial-portion vertical side of the sacrificial portion to the component. The vertical tether physically connects the component to the surface, extends a horizontal tether distance from the component along the surface in a horizontal direction directly away from the sacrificial-portion vertical side and parallel to the source-wafer surface, and extends no more than the horizontal tether distance beyond a component periphery surrounding the component in the horizontal direction.

### CROSS REFERENCE TO RELATED APPLICATIONS

This patent application is related to U.S. patent application Ser. No. 18/120,397 entitled Vertical Tethers for Micro-Transfer Printing, filed Mar. 12, 2023, by Thostenson et al, the disclosure of which is hereby incorporated by reference herein in its entirety.

### TECHNICAL FIELD

The present disclosure relates to structures and methods for tethering micro-transfer printable integrated circuits on source wafers.

### BACKGROUND

Integrated circuits (ICs) are widely used in electronic devices. Integrated circuits are typically formed on a semiconductor wafer using photolithographic processes and then packaged, for example in a ceramic or plastic package, with pins or bumps on the package providing externally accessible electrical connections to the integrated circuit.

In some applications, the bare integrated circuit dies are not separately packaged but are placed directly on a destination substrate and electrically connected on the destination substrate, for example using photolithographic, integrated circuit, or printed-circuit-board methods, to form an electronic system. However, this can be difficult to accomplish when the integrated circuits are small. Thus, an efficient method for transferring bare dies from a relatively small and expensive source substrate (e.g., a crystalline semiconductor) to a relatively large and inexpensive destination substrate (e.g., amorphous glass, resin, or plastic) is very desirable, since the integrated circuits can provide much higher data-processing efficiency than thin-film semiconductor structures formed on large substrates.

One approach to handling and placing small integrated circuits (chiplets) uses micro-transfer printing, for example as described in U.S. Pat. Nos. 8,722,458, 7,622,367 and 8,506,867, each of which is hereby incorporated by reference in its entirety. In these methods, an integrated circuit is formed on a source wafer, for example a semiconductor wafer, and undercut by etching a gap between a bottom side of the integrated circuit and the source wafer. A stamp contacts a top side of the integrated circuit to adhere the integrated circuit to the stamp, the stamp and integrated circuit are removed from the source wafer and transported to a target (destination) substrate, for example a semiconductor, glass, or plastic substrate, the integrated circuit is contacted and adhered to the target substrate, and the stamp removed to “pick” the integrated circuit from the source wafer and “print” it to the target substrate. Multiple integrated circuits can be transfer-printed in a common step with a single stamp. The integrated circuits can then be electrically connected using conventional photolithographic and printed-circuit board methods. This technique has the advantage of locating many (e.g., tens of thousands to millions) small integrated circuit devices on a target substrate in a single print step. For example, U.S. Pat. No. 8,722,458 teaches transferring light-emitting, light-sensing, or light-collecting semiconductor elements from a wafer substrate to a destination substrate using a patterned elastomer stamp whose spatial pattern matches the location of the semiconductor elements on the wafer substrate.

There is a need, therefore, for improvements in processes and structures for making robust releasable integrated circuit in a reliable, efficient, and cost-effective manner.

### SUMMARY

In embodiments of the present disclosure, among other things, a micro-transfer-printable component source structure (e.g., a component source wafer comprising components suitable for micro-transfer printing) comprises a source wafer having a source-wafer surface and a sacrificial layer patterned to comprise one or more sacrificial portions comprising a sacrificial material. Each sacrificial portion can be disposed on only a portion of the source-wafer surface and can have a sacrificial-portion vertical side extending along a side of the sacrificial portion in a direction at least partially orthogonal to the source-wafer surface. A component can be disposed on the sacrificial portion, for example the component can be disposed directly on and entirely over the sacrificial portion so that all of the component is separated from the source wafer by the sacrificial portion. The component can have a component vertical side extending along a side of the component in a direction at least partially orthogonal to the source-wafer surface.

A vertical tether can extend in an at least partially vertical direction orthogonal to the source-wafer surface along a sacrificial-portion vertical side of the sacrificial portion to the component to physically connect the component to the source-wafer surface. The vertical tether can extend a horizontal tether distance from the component along the source-wafer surface in a horizontal direction directly away from the sacrificial-portion vertical side (and the component vertical side) and parallel to the source-wafer surface no more than the horizontal tether distance beyond a component periphery surrounding the component in the horizontal direction. The component can be disposed directly and exclusively on the sacrificial portion or can be disposed directly and exclusively on the sacrificial portion in combination with the vertical tether. The horizontal tether distance can be a distance from the component to the farthest extent of the vertical tether from the component, for example on the source-wafer surface, in a horizontal direction parallel to the source-wafer surface.

In some embodiments, the component comprises a component vertical side that extends along the component at least partially in the vertical direction and the vertical tether extends at least partially along and in contact with the component vertical side. In some embodiments, the vertical tether extends onto a component top side of the component opposite the source-wafer surface, for example, in a direction substantially parallel to the source-wafer surface. In some embodiments, the vertical tether is operable to break (e.g., fracture) in response to a stamp post adhered to a component top side of the component opposite the source-wafer surface pulling the component away from the source-wafer surface.

Embodiments of the present disclosure can include a micro-transfer-printable component source structure that comprises multiple vertical tethers extending at least partially in the vertical direction from the source-wafer surface along at least a portion of one or more sacrificial-portion vertical sides of the sacrificial portion to the component and physically connecting the component to the source-wafer surface. The component periphery can comprise multiple component vertical sides, the multiple component vertical sides defining a polygon, each component vertical side can extend at least partially in the vertical direction, and a vertical tether of the multiple vertical tethers can be disposed along each component vertical side of the multiple component vertical sides. According to some embodiments of the present disclosure, the horizontal tether distance can be less than a thickness of the component, less than a thickness of the patterned sacrificial layer in the vertical direction, or both.

In some embodiments, the vertical tether has a variable tether width in a direction orthogonal to the horizontal direction and parallel to the source-wafer surface. In some embodiments, the variable tether width can have a minimum width adjacent to the sacrificial portion in the horizontal direction. In some embodiments, the minimum width can be disposed substantially at a sacrificial-portion top side of the sacrificial portion opposite and substantially parallel to the source-wafer surface. In some embodiments, the vertical tether can have a variable tether thickness in a direction parallel to the horizontal direction. In some embodiments, the variable tether thickness can have a minimum thickness (e.g., a minimum width) adjacent to the sacrificial portion in the horizontal direction. In some embodiments, the minimum thickness (e.g., a minimum width) can be disposed substantially at a sacrificial-portion top side of the sacrificial portion opposite the source-wafer surface.

According to some embodiments of the present disclosure, the vertical tether can comprise a tether material, the tether material can also be disposed on a component top side of the component opposite the source wafer, and a thickness of the vertical tether in the horizontal direction can be no greater than a thickness of the tether material disposed on the component top side.

According to some embodiments of the present disclosure, a micro-transfer-printable component source structure can comprise a source wafer having a source-wafer surface, a patterned sacrificial layer comprising a sacrificial material disposed on only a portion of the source-wafer surface forming multiple separate sacrificial portions. For each of the sacrificial portions, a respective component can be disposed on the sacrificial portion, for example, disposed directly on and entirely over the sacrificial portion. A vertical tether can extend in an at least partially vertical direction orthogonal to the source-wafer surface along a sacrificial-portion vertical side of each of the sacrificial portions to the component disposed on the sacrificial portion. Each vertical tether can physically connect the component to the source-wafer surface. The vertical tether can extend a horizontal tether distance from the component to the source-wafer surface in a horizontal direction directly away from the sacrificial-portion vertical side and parallel to the source-wafer surface. The sacrificial portion can extend no more than the horizontal tether distance beyond a component periphery surrounding the component in a direction parallel to the source-wafer surface. A distance in the horizontal direction between adjacent components can be less than or no greater than twice the horizontal tether distance.

According to some embodiments of the present disclosure, a micro-transfer-printable component source structure can comprise a source wafer having a source-wafer surface, a sacrificial layer (e.g., a patterned sacrificial layer) comprising a sacrificial material disposed on the source-wafer surface, the sacrificial layer comprising one or more tether via(s) extending through the sacrificial layer to the source-wafer surface, a component disposed on (e.g., directly on) and entirely over the sacrificial layer, and a vertical tether extending away (e.g. orthogonally away) from the source-wafer surface to the component through each of the one or more tether via(s). Each vertical tether can physically connect the component to the source-wafer surface. Some embodiments can comprise multiple components disposed on the sacrificial layer. The vertical tether can extend a horizontal tether distance from the component along the source-wafer surface in a horizontal direction directly away (e.g. orthogonally away) from the sacrificial-portion vertical side and parallel to the source-wafer surface. A distance between adjacent ones of the multiple components can be less than or no greater than twice the horizontal tether distance.

According to some embodiments of the present disclosure, a micro-transfer-printable component source structure can comprise a source wafer having a source-wafer surface, a component disposed over the source-wafer surface, and one or more vertical tether(s) extending orthogonally from the source-wafer surface to the component. Each vertical tether can physically connect the component to the source-wafer surface. A gap can separate the component from the source-wafer surface. The one or more vertical tether(s) can suspend the component over the source-wafer surface.

According to some embodiments of the present disclosure, a micro-transfer-printable component target structure can comprise a target substrate having a target-substrate surface, an adhesive layer having an adhesive-layer thickness disposed on the target substrate surface, a component disposed on the adhesive layer, and one or more vertical tether(s) extending into the adhesive layer beyond a component bottom side of the component, for example, adjacent and substantially parallel to the target substrate, by a vertical-tether distance. The vertical-tether distance can be no greater than the adhesive layer thickness. Some embodiments can comprise a mechanical structure disposed on the target substrate and a component vertical side of the component can extend at least partially orthogonal to the target substrate or one of the one or more vertical tethers can be substantially in contact with the mechanical structure. A vertical tether can be substantially transparent.

According to some embodiments of the present disclosure, a method of making a micro-transfer-printable component source structure can comprise providing a source wafer having a source-wafer surface, a patterned sacrificial layer forming a sacrificial portion disposed on the source-wafer surface, and a component disposed on the sacrificial portion, and forming a vertical tether extending in an at least partially vertical direction orthogonal from the component to the source-wafer surface. The vertical tether can extend along and in contact with a component vertical side of the component and a sacrificial-portion vertical side of the sacrificial portion. The vertical tether can physically connect the component to the source-wafer surface. The vertical tether can extend a horizontal tether distance from the component to the source-wafer surface in a horizontal direction directly away from the sacrificial-portion vertical side and parallel to the source-wafer surface. The sacrificial portion can extend no more than the horizontal tether distance beyond a component periphery surrounding the component in the horizontal direction. Some embodiments can comprise etching the sacrificial portions to form a gap between the component and the source-wafer surface. Some embodiments can comprise contacting the component with a stamp to adhere the component to the stamp and removing the component from the source wafer with the stamp to break (e.g., fracture) the vertical tether.

According to some embodiments of the present disclosure, a method of making a micro-transfer-printable component source structure can comprise providing a source wafer having a source-wafer surface, a sacrificial layer disposed on the source-wafer surface, and a component disposed entirely on the sacrificial layer, forming one or more tether via(s) extending through the sacrificial layer to the source-wafer surface adjacent to the component, and forming a vertical tether extending in an at least partially vertical direction orthogonal from the component to the source-wafer surface that physically connects the component to the source-wafer surface through each of the one or more tether via(s), and etching the sacrificial layer to form a gap separating the component from the source-wafer surface.

According to some embodiments of the present disclosure, a micro-transfer-printable component source structure can comprise a source wafer having a source-wafer surface, a patterned sacrificial layer forming an isolated sacrificial portion, a component disposed on and entirely over the sacrificial portion, and a vertical tether extending vertically from the source-wafer surface along a vertical side of the sacrificial portion to the component such that the vertical tether physically connects the component to the source-wafer surface. In some embodiments, the vertical tether extends a horizontal tether distance from the component along the source-wafer surface in a horizontal direction directly away from the sacrificial-portion vertical side and parallel to the source-wafer surface. In some embodiments, the sacrificial portion extends no more than the horizontal tether distance beyond a component periphery surrounding the component in the horizontal direction.

In embodiments, each vertical tether can physically connect the component to the source-wafer surface. In embodiments, each vertical tether can extend a horizontal tether distance from the component to the source-wafer surface in a horizontal direction directly away from the sacrificial-portion vertical side and parallel to the source-wafer surface.

In some embodiments, the component comprises a component material and the source wafer comprises a source wafer material that is the same as the component material. In some embodiments, the sacrificial portion comprises a sacrificial-portion material and the component comprises a component material that is differentially etchable from the sacrificial-portion material. In some embodiments, the component comprises a component material and the source wafer comprises a source wafer material that is differentially etchable from the component material. In some embodiments, the sacrificial portion comprises a sacrificial-portion material and the source wafer comprises a source wafer material that is differentially etchable from the sacrificial-portion material. The source wafer and the component can comprise the same or different materials, for example semiconductor materials.

In some embodiments, the component vertical side extends at an angle no less than 45 degrees from the source-wafer surface, e.g., at least partially in a vertical direction orthogonal to the source-wafer surface. In some embodiments, the sacrificial-portion vertical side extends orthogonally from the source-wafer surface. In some embodiments, the sacrificial-portion vertical side extends at an angle no less than 45 degrees from the source-wafer surface, e.g., at least partially in a vertical direction orthogonal to the source-wafer surface. A “vertical side” of the component or sacrificial portion can comprise a component edge or sacrificial-portion edge and can extend substantially or at least partially vertically from the source-wafer surface. A “top side” or “bottom side” can extend substantially parallel to the source-wafer surface, e.g., a bottom surface or side adjacent or closest to the source-wafer surface or a top surface or side opposite and farthest from the source-wafer surface. The term “horizontal” refers to directions that are substantially parallel to the source-wafer surface and the term “vertical” refers to directions that are orthogonal or at least partially perpendicular to the source-wafer surface.

In some embodiments, the vertical tether extends vertically along and in contact with some but less than all of the component vertical side (or component edge). In some embodiments, the vertical tether extends vertically along and in contact with some but less than all of the sacrificial-portion vertical side (or sacrificial-portion edge). In some embodiments, the vertical tether extends horizontally along and on at least a part of the source-wafer surface, for example directly or orthogonally away from the component or sacrificial portion. In some embodiments, the vertical tether extends horizontally along and on at least a part of the source-wafer surface a horizontal tether distance that is no greater than a thickness of a portion of the vertical tether in contact with the component vertical side or a portion of the vertical tether in contact with the sacrificial-portion vertical side. In some embodiments, the vertical tether extends horizontally along and on at least a part of the source-wafer surface a horizontal tether distance that is greater than a thickness of a portion of the vertical tether in contact with the component vertical side or a portion of the vertical tether in contact with the sacrificial-portion vertical side.

The vertical tether can comprise a sacrificial-portion portion disposed on or in contact with the sacrificial portion (e.g., on a sacrificial-portion vertical side) and a component portion disposed on or in contact with the component (e.g., on a component vertical side). In embodiments, the sacrificial-portion portion can be narrower (or thinner) or have a narrower or thinner part (or neck) than the component portion, for example in a width direction or in a thickness direction. The width direction can be along and in a direction substantially parallel to a component vertical side of the component or substantially parallel to a sacrificial-portion vertical side of the sacrificial portion and substantially parallel to the source-wafer surface. The thickness direction can be substantially orthogonal to a component vertical side of the component or substantially orthogonal to a sacrificial-portion vertical side of the sacrificial portion. The neck can be substantially and at least partially in a common plane with an interface between the component and the sacrificial portion. The neck can form or define a portion (e.g., a break (e.g., fracture) point or break (e.g., fracture) line) of the vertical tether that preferentially breaks (e.g., fractures) during micro-transfer printing.

In some embodiments, the vertical tether comprises an inorganic material, an organic material, or comprises layers comprising organic and inorganic materials, for example in alternation. In some embodiments, the vertical tether comprises silicon oxide, silicon nitride, a resin, an epoxy, polyimide, a photoresist, or a combination of these. In some embodiments, the vertical tether is adjacent to the component or to the sacrificial portion. The vertical tether can extend along and on at least a part of the source wafer.

The vertical tether can extend along and in contact with some but less than all of a component top side of the component opposite the source wafer.

In embodiments, the component is suspended over the source wafer by one or more vertical tether(s) such that the component is separated from the source wafer by a gap, for example when the patterned sacrificial portion is etched away to form the gap between the source-wafer surface and the component, for example between a component bottom side of the component adjacent or closest to the source-wafer surface and the source wafer.

Some methods according to the present disclosure comprise contacting the component with a stamp to adhere the component to the stamp and removing the component from the source wafer with the stamp to break (e.g., fracture) the vertical tether. Methods can comprise breaking (e.g., fracturing) the vertical tether between the component and the source-wafer surface in a direction orthogonal to the source-wafer surface. The step of disposing the sacrificial portion on the source-wafer surface can comprise disposing a sacrificial layer over the source-wafer surface and patterning the sacrificial layer to form the sacrificial portion. The step of forming the vertical tether can comprise coating an encapsulation layer, metal layer, oxide layer, or nitride layer over the component and the source-wafer surface and patterning the encapsulation layer, metal layer, oxide layer, or nitride layer to form the vertical tether. The patterning step can be a common step with making structures of, in, or with the component.

According to embodiments of the present disclosure, a method of making a micro-transfer-printable target structure comprises providing a target substrate having a target-substrate surface, providing a component reversibly adhered to a stamp, the component having a component edge extending along a component vertical side of the component in a direction at least partially orthogonal to the target-substrate surface, contacting the component to the target substrate or a layer disposed on the target substrate with the stamp to adhere the component to the target-substrate surface, and removing the stamp, leaving the component adhered to the target substrate. The layer can be an adhesive layer, and the component can be adhered to the target substrate with the adhesive layer. The component can be subsequently electrically or optically connected to the target substrate or other structures or components on the target substrate using photolithographic methods and materials.

The present disclosure provides structures and methods for efficiently forming robust releasable integrated circuits for micro-transfer printing in a cost-effective manner.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIGS. 1A-1H are sequential perspectives and cross sections each taken across cross-section line A of the corresponding perspective and, in FIG. 1E, a top or plan view of structures for constructing a micro-transfer-printable component source structure according to illustrative embodiments of the present disclosure;

FIG. 2A is a cross section of a micro-transfer-printable component source structure showing a vertical tether thickness according to illustrative embodiments of the present disclosure;

FIG. 2B is a side view of a micro-transfer-printable component source structure showing a vertical tether width according to illustrative embodiments of the present disclosure;

FIG. 3 is a plan view of a micro-transfer-printable component source structure according to illustrative embodiments of the present disclosure;

FIG. 4 is a plan view of a micro-transfer-printable component source structure having increased component density over the source wafer compared to FIG. 3 according to illustrative embodiments of the present disclosure;

FIG. 5A is a perspective and cross section taken along cross-section line A of a micro-transfer-printable component source structure showing tether vias according to illustrative embodiments of the present disclosure;

FIG. 5B is a perspective and cross section taken along cross-section line A of a micro-transfer-printable component source structure showing tethers in tether vias according to illustrative embodiments of the present disclosure;

FIG. 6 is a perspective and cross section taken along cross-section line A of a micro-transfer-printable component source structure showing tethers suspending the component over a gap according to illustrative embodiments of the present disclosure;

FIG. 7 is a flow diagram of methods according to illustrative embodiments of the present disclosure;

FIG. 8 is a flow diagram of methods according to illustrative embodiments of the present disclosure;

FIG. 9 is a flow diagram of methods according to illustrative embodiments of the present disclosure;

FIG. 10 is a cross section of a micro-transfer-printable component source structure showing vertical tether thickness, break (e.g., fracture) lines, and horizontal tether distance for a released component according to illustrative embodiments of the present disclosure;

FIG. 11 is a cross section of a micro-transfer-printable component target structure comprising an adhesive layer and broken (e.g., fractured) vertical tethers extending into the adhesive layer a distance less than a thickness of the adhesive layer according to illustrative embodiments of the present disclosure; and

FIG. 12 is a cross section of a micro-transfer-printable component target structure comprising a mechanical structure in substantial contact with a vertical tether according to illustrative embodiments of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not drawn to scale since the variation in size of various elements in the Figures is too great to permit depiction to scale.

### DETAILED DESCRIPTION OF CERTAIN EMBODIMENTS

Among other things, embodiments of the present disclosure provide structures and methods for efficiently providing robust releasable components (e.g., integrated circuits) and structures in or on a source wafer or source substrate for micro-transfer printing to a target (destination) substrate in a cost-effective and efficient manner. Embodiments can enable source wafers or source substrates with a greater density of micro-transfer-printable micro-devices made using fewer processing steps, thereby reducing costs for micro-systems made using micro-transfer printing. Some embodiments can also provide more robust structures with greater micro-transfer-printing yields. In some implementations, components can be micro-transfer printed onto target substrates closer together or closer to structures disposed on the target substrates.

Micro-transfer printing and/or dry transfer printing can comprise removing a released or suspended component from a source wafer and transferring the removed component to a target (destination) substrate with a stamp. A released component is one whose underlying sacrificial portion has been etched to suspend the released component over the source wafer. For example, using an optomechatronic motion-control printer, a micro-transfer print method can comprise contacting a visco-elastic stamp to a component on a source wafer to adhere the component to the stamp, removing the component from the source wafer (thereby breaking (e.g., fracturing) or separating a tether physically connecting the component to an anchor portion of the source wafer), locating the component and stamp in alignment with a target substrate, pressing the component against the target substrate to adhere the component to the target substrate, and removing the stamp from the target substrate, leaving the component adhered to the target substate. In such a micro-transfer printing process, it is important that the tether breaks (e.g., fractures) in a controlled manner in a high-yield manufacturing process.

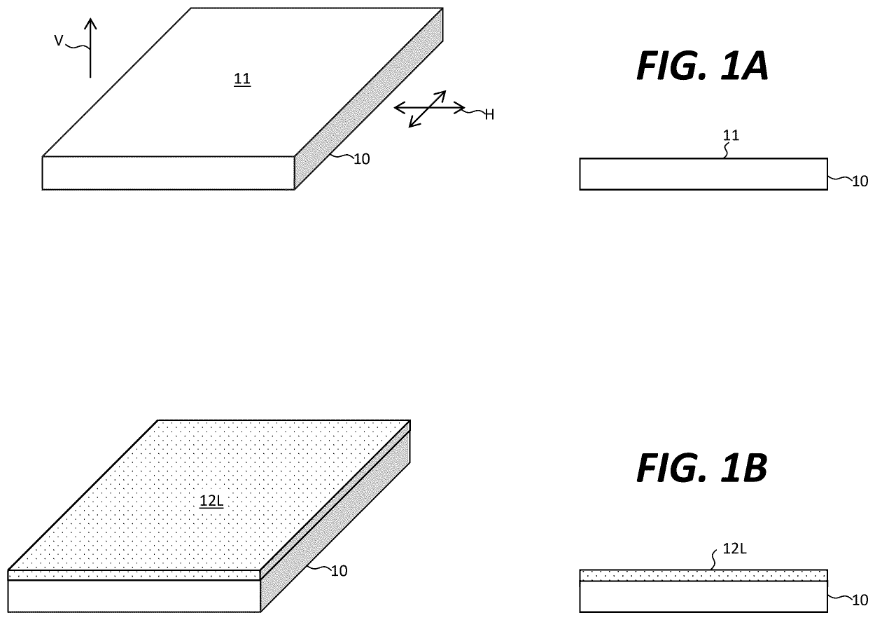

According to embodiments of the present disclosure and as shown in the successive construction steps of FIGS. 1A-1H, a micro-transfer-printable component source structure 90 can comprise a source wafer 10 (e.g., a source substrate 10) having a source-wafer surface 11 (FIG. 1A), a sacrificial layer 12L comprising a sacrificial material (FIG. 1B) disposed on source-wafer surface 11, a component 20 disposed on sacrificial layer 12L (FIG. 1C), for example in an epitaxial layer (not shown), the sacrificial layer 12L patterned forming a sacrificial portion 12 with a component 20 disposed on sacrificial portion 12 (FIG. 1D), sacrificial portion 12 covering only a portion of source-wafer surface 11. Component 20 can be disposed directly on and entirely over sacrificial portion 12 (FIG. 1E). Vertical tether 40 can be formed to extend in an at least partially vertical direction V orthogonal to source-wafer surface 11 along a sacrificial-portion vertical side 12E of sacrificial portion 12 to component 20 and for example along at least a portion of component vertical side 20E of component 20, e.g., does not necessarily cover the entire component vertical side 20E or sacrificial-portion vertical side 12E, as shown in FIG. 1E.

Vertical tether 40 can physically connect component 20 to source-wafer surface 11. Vertical tether 40 can extend a horizontal tether distance 46 from component 20 to and along source-wafer surface 11 in a horizontal direction H at least partially orthogonal to sacrificial-portion vertical side 12E and parallel to source-wafer surface 11 so that vertical tether 40 extends a horizontal tether distance 46 directly away from component 20 and sacrificial portion 12 along source-wafer surface 11, for example at right angles to component 20 and sacrificial portion 12 and not along or partially parallel to component 20 and sacrificial portion 12. For example, horizontal tether distance 46 can extend parallel to source-wafer surface 11 and orthogonal to a line on component vertical side 20E or sacrificial-portion vertical side 12E parallel to source-wafer surface 11. If component vertical side 20E or sacrificial-portion vertical side 12E is not completely or substantially vertical with respect to source-wafer surface 11, horizontal tether distance 46 can extend in a direction that is a projection of a normal of component vertical side 20E or sacrificial-portion vertical side 12E projected onto source-wafer surface 11. The projection is a direction directly away from component vertical side 20E or sacrificial-portion vertical side 12E parallel to source-wafer surface 11.

Sacrificial portion 12 can extend no more than horizontal tether distance 46 beyond a component periphery 20P surrounding component 20 in horizontal direction H. FIG. 1E illustrates a different horizontal direction H for each of four vertical tethers 40 disposed adjacent to and in contact with (e.g., direct contact with) a corresponding different component vertical side 20E of component 20 extending directly away from component 20, e.g., for each component vertical side 20E of a rectangular component 20. In some embodiments, multiple sacrificial portions 12 are patterned from sacrificial layer 12L and a component 20, e.g., a single component 20, can be disposed on each sacrificial portion 12 so that micro-transfer-printable component source structure 90 can comprise a plurality of sacrificial portions 12 and components 20.

In part because vertical tethers 40 can support component 20 in a vertical direction V rather than horizontally, vertical tethers 40 can be very thin, for example only a few microns, e.g., no greater than five microns, no greater than two microns, no greater than one micron, or less than one micron thick, especially if multiple vertical tethers 40 are used to support component 20 over source wafer 10, as shown in FIG. 1E.

Sacrificial portions 12 can be formed from sacrificial layer 12L either before components 20 are disposed on the sacrificial material or after (as shown in FIGS. 1C, 1D). For example, in some embodiments a layer of epitaxial material (e.g., an epitaxial layer, not shown in the Figures) can be disposed on sacrificial layer 12L and processed to form components 20, after which sacrificial layer 12L is patterned to form sacrificial portions 12. In some embodiments an epitaxial layer can be disposed on sacrificial layer 12L and the epitaxial layer and sacrificial layer 12L processed to form sacrificial portions 12, after which components 20 are formed on sacrificial portions 12. In some embodiments, a semiconductor-on-insulator wafer is provided and then processed as in FIG. 1C to form components 20 and then remaining epitaxy and sacrificial layer 12L are patterned to form sacrificial portions 12 and components 20 so that components 20 can each be disposed directly on and entirely over a corresponding sacrificial portion 12. The epitaxial material can be the same as or comprise a common material with a material comprising source wafer 10. Processing steps for source wafer 10, component 20, and sacrificial portions 12 can include photolithographic deposition (e.g., evaporating, sputtering, and coating) steps and patterning (e.g., using photoresist deposition, photoresist patterning, material etching, and photoresist stripping) known in the integrated circuit industry.

As shown in FIG. 1F, sacrificial portions 12 can be etched to suspend components 20 over source wafer 10 with vertical tethers 40, so that a stamp 60 having a stamp post 62 adhered to a top side of component 20, as shown in FIG. 1G, can remove component 20 from source wafer 10 and break (e.g., fracture) vertical tethers 40, forming broken (e.g., fractured) vertical tethers 42, as shown in FIG. 1H, and micro-transfer print components 20 from source wafer 10. (The perspectives of FIGS. 1G and 1H omit a stamp 60 rigid support for stamp post 62 but is shown in the cross section.)

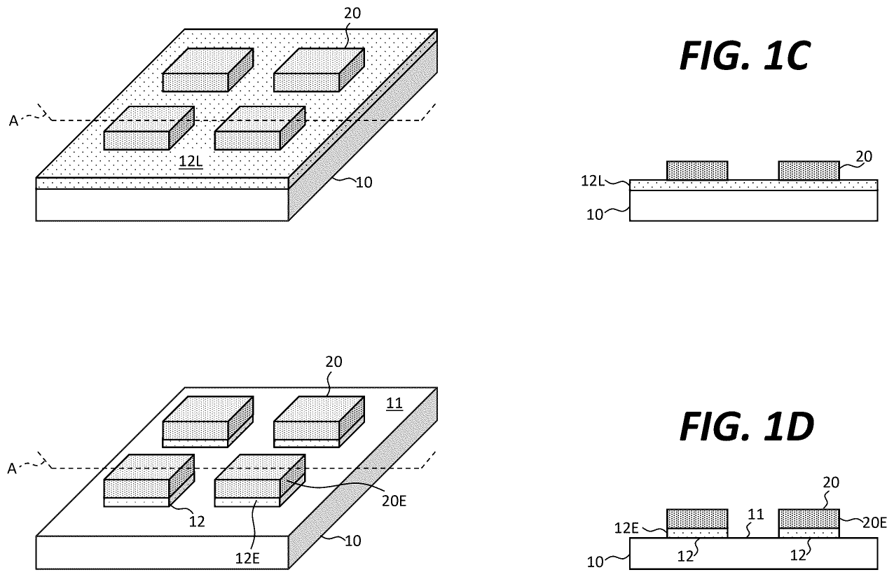

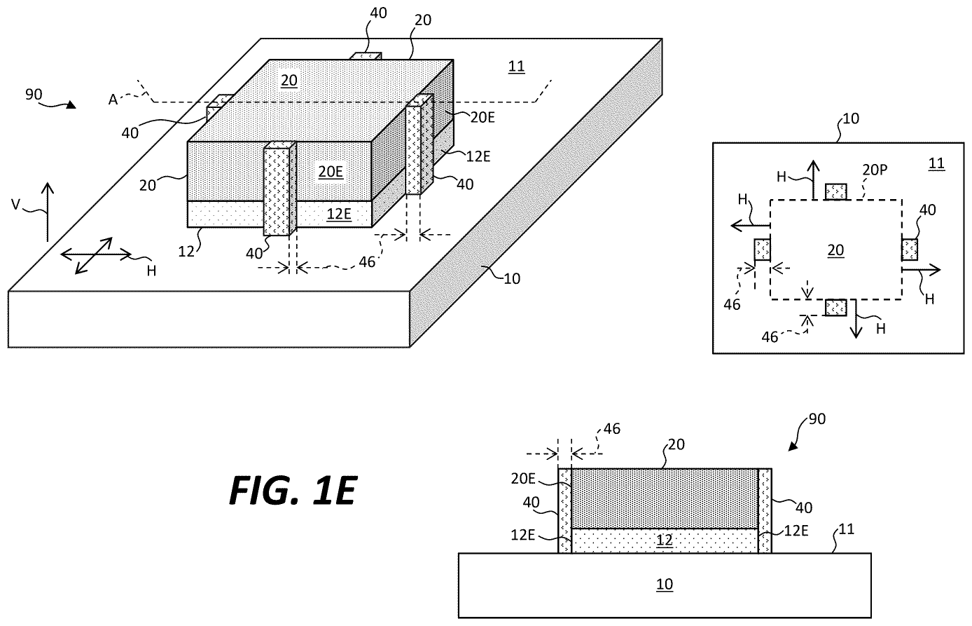

Component(s) 20 can each comprise a component vertical side 20E that extends along a side of component 20 at least partially in vertical direction V and vertical tether 40 can extend at least partially along and in contact with (e.g., direct contact with) at least a portion of component vertical side 20E. As used herein, component 20 and sacrificial portion 12 have sides (e.g., substantially planar sides) and the sides that are at least partially or substantially orthogonal (e.g., within manufacturing tolerances) to source-wafer surface 11 are referred to as sides or edges, e.g., component vertical side 20E and sacrificial-portion vertical side 12E, respectively. In embodiments, component vertical side 20E and sacrificial-portion vertical side 12E are not completely vertical due to process and material constraints, so that vertical tether 40 extends only partially vertically from source-wafer surface 11 to component 20. Top sides and bottom sides of components 20 and of sacrificial portions 12 can both be substantially parallel to source-wafer surface 11. The bottom sides can be adjacent to source-wafer surface 11 and the top sides on a side opposed to source-wafer surface 11. (Adjacent means no other side (e.g., the top side) is between the bottom side and the source-wafer surface 11. Opposed means another side (e.g., the bottom side) is between the top side and the source-wafer surface 11.) The bottom side of component 20 can be in contact with or adjacent to the top side of sacrificial portion 12, for example component 20 can be directly disposed on and in contact with sacrificial portion 12 or an intervening layer (e.g., an etch-stop layer) can be disposed between component 20 and sacrificial portion 12. In some embodiments, component 20 comprises an etch-stop layer on or as the bottom of component 20 adjacent to sacrificial portion 12. Vertical tether 40 can extend onto the top side of component 20 in a direction at least partially parallel to source-wafer surface 11, as shown in FIG. 2A. Where vertical tether 40 extends onto the top side of component 20, it can serve as structural reinforcement for relatively thin components 20 (e.g., having a thickness no greater than five microns, no greater than two microns, or no greater than one micron) when components 20 are released by etching sacrificial portion 12, as the etch process can stress components 20, e.g., with bubbles from the etching, and prevent cracks from forming in components 20.

In embodiments and as shown in FIG. 2A, multiple vertical tethers 40 can extend at least partially in vertical direction V from source-wafer surface 11 along one or more sacrificial-portion vertical sides 12E of sacrificial portion 12 to component 20. Each of the multiple vertical tethers 40 can physically connect component 20 to source-wafer surface 11 and source wafer 10. In embodiments, component periphery 20P is a polygon (e.g., a rectangle) comprising multiple component vertical sides 20E (multiple component edges 20E) extending at least partially orthogonally to source-wafer surface 11 and therefor comprising component vertical sides 20E (e.g., four component vertical sides 20E, one for each side of a rectangular component 20), each component vertical side 20E extending at least partially in vertical direction V. A vertical tether 40 of the multiple vertical tethers 40 can be disposed along each component vertical side 20E of the multiple component vertical sides 20E, e.g., as shown in FIG. 1E and can have a thickness 40T in a direction orthogonal to component vertical side 20E (as shown in FIG. 2A). In some embodiments, a vertical tether 40 is not disposed on a sacrificial-portion vertical side 12E. In some embodiments, multiple vertical tethers 40 are disposed on or in contact with (e.g., direct contact with) one or more a sacrificial-portion vertical sides 12E.

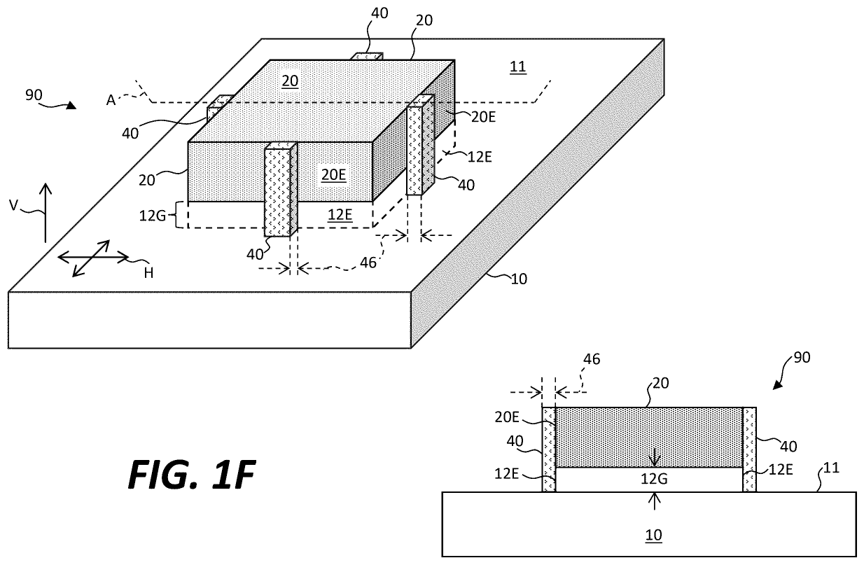

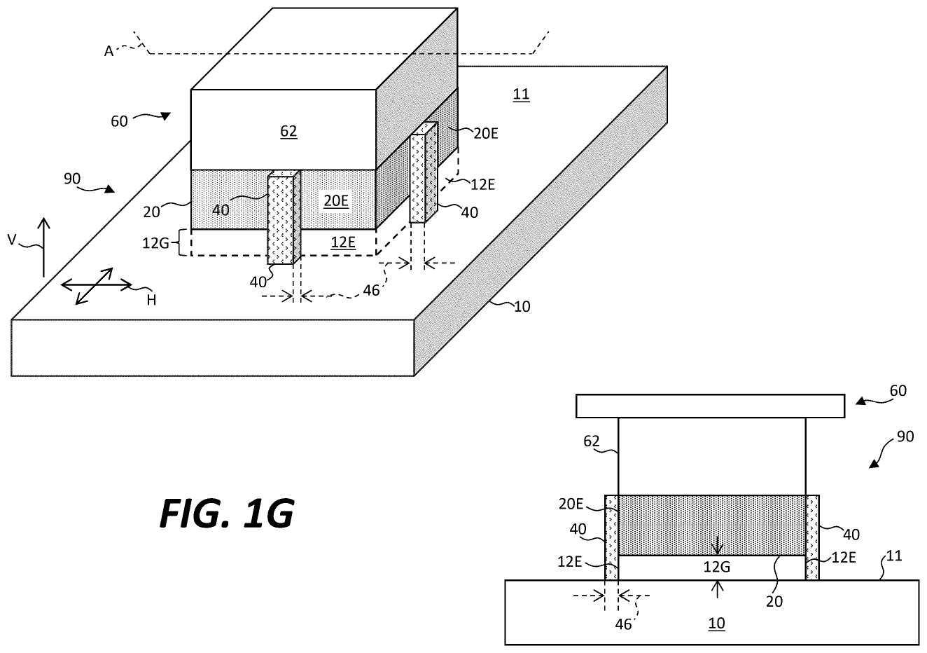

In embodiments of the present disclosure and as shown in FIG. 4 compared to FIG. 3, components 20 can be disposed over source wafer at a greater density by restricting horizontal distance 46 and vertical tether thickness 40T of vertical tether 40 in horizontal direction H parallel to source-wafer surface 11 and orthogonal to component vertical side 20E on along which vertical tether 40 is disposed. Note that horizontal direction H can be different for different component vertical sides 20E since they are on different component vertical sides 20E, e.g., different sides of a polygon or rectangle. Horizontal tether distance 46 can be less than a thickness of component 20 or less than a thickness of sacrificial portion 12 in vertical direction V (e.g., in a direction orthogonal to source-wafer surface 11). As shown in FIG. 3, a component separation W1 is greater than twice horizontal tether distance W2. In contrast, as shown in FIG. 4 and according to embodiments of the present invention, vertical tethers 40 connected to different components 20 are laterally offset over source wafer 10 and component separation W1 is less than twice horizontal tether distance W2.

To facilitate vertical tether 40 breaking (e.g., fracturing) during picking component 20 while micro-transfer printing, vertical tether 40 can have a variable tether width 40W in a direction orthogonal to horizontal direction H and parallel to source-wafer surface 11, e.g., horizontally along component vertical side 20E corresponding to vertical tether 40, as shown in FIG. 2B. Variable tether width 40W can have a minimum width 44 adjacent to sacrificial portion 12 in a horizontal direction parallel to component vertical side 20E. Minimum width 44 can be disposed substantially at a top side of sacrificial portion 12 opposite source-wafer surface 11, e.g., just below or at the bottom side of component 20. In some embodiments, vertical tether 40 has a variable tether thickness 40T in a direction parallel to horizontal direction H, e.g., orthogonally to component vertical side 20E. Variable tether thickness 40T can have a minimum thickness adjacent to sacrificial portion 12 disposed substantially at a top side of sacrificial portion 12 opposite source-wafer surface 11, e.g., just below or at the bottom side of component 20. The minimum in either (or both) cases can be a narrowing of vertical tether 40, e.g., forming a tether neck 44 or narrower portion of vertical tether 40 connecting a portion attached to component 20 and a portion attached to sacrificial portion 12 or source-wafer surface 11.

In some embodiments of the present disclosure, a micro-transfer-printable component source structure 90 can comprise a source wafer 10 having a source-wafer surface 11, a patterned sacrificial layer 12L comprising a sacrificial material disposed on only a portion of source-wafer surface 11 forming multiple separate sacrificial portions 12, a component 20 disposed on each of sacrificial portions 12, wherein a component 20 can be disposed directly on and entirely over sacrificial portion 12, and a vertical tether 40 extending in an at least partially vertical direction V orthogonal to source-wafer surface 11 along a sacrificial-portion vertical side 12E of each of sacrificial portions 12 to component 20 disposed on (e.g., directly on and in contact with) sacrificial portion 12 and component 20, e.g., at least a portion of component vertical side 20E. Each vertical tether 40 can physically connect component 20 to source-wafer surface 11. Each vertical tether 40 can extend a horizontal tether distance 46 from component 20 to source-wafer surface 11 in a horizontal direction H orthogonal to sacrificial-portion vertical side 12E and parallel to source-wafer surface 11. Sacrificial portion 12 can extend no more than horizontal tether distance 46 beyond component periphery 20P surrounding component 20 in a direction parallel to source-wafer surface 11. A distance in horizontal direction H between adjacent components 20 can be less than twice horizontal tether distance 46 (e.g., as shown in FIG. 4).

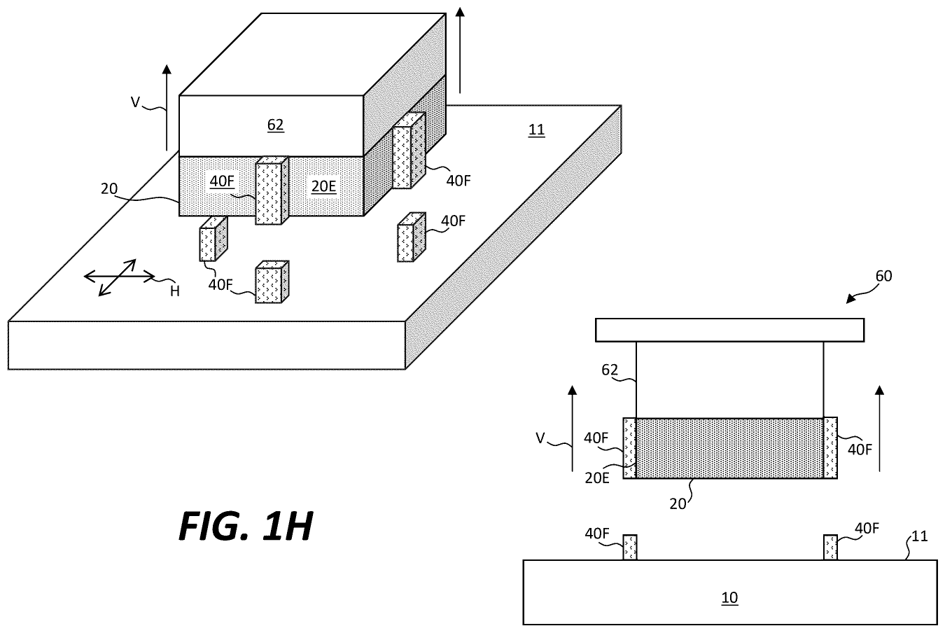

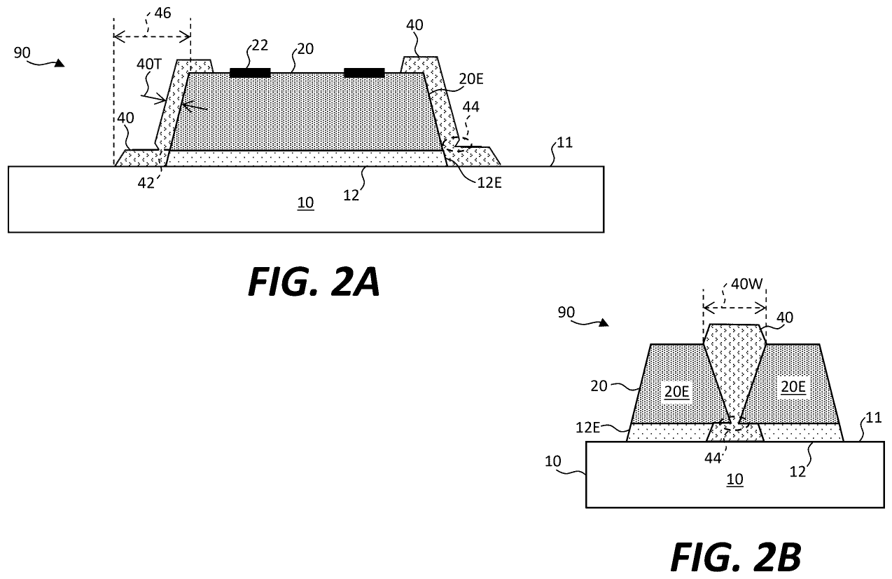

According to embodiments of the present disclosure and as shown in FIGS. 5A and 5B, a micro-transfer-printable component source structure 90 can comprise a source wafer 10 having a source-wafer surface 11, a sacrificial layer 12L comprising a sacrificial material disposed on source-wafer surface 11, sacrificial layer 12L comprising one or more tether vias 48 extending through sacrificial layer 12L to source-wafer surface 11, a component 20 disposed directly on and entirely over sacrificial layer 12L (as shown in FIG. 5A), and a vertical tether 40 extending orthogonally from source-wafer surface 11 to component 20 through each of one or more tether vias 48, wherein each vertical tether 40 physically connects component 20 to source-wafer surface 11 (as shown in FIG. 5B). In embodiments, sacrificial layer 12L can be etched with an etchant so that components 20 are suspended over source wafer 10 by vertical tethers 40.

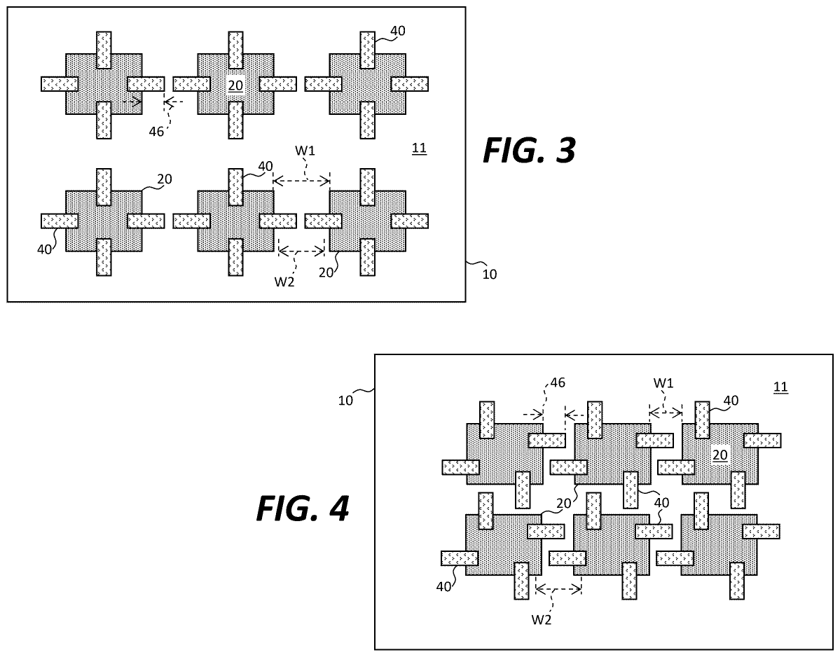

Thus, according to embodiments of the present disclosure and as shown in the perspective and cross section along cross section line A of FIG. 6, a micro-transfer-printable component source structure 90 can comprise a source wafer 10 having a source-wafer surface 11, a component 20 disposed over source-wafer surface 11, and one or more vertical tethers 40 extending orthogonally from source-wafer surface 11 to component 20, wherein each vertical tether 40 physically connects component 20 to source-wafer surface 11, a gap 12G separates component 20 from source-wafer surface 11, and one or more vertical tethers 40 suspend component 20 over source-wafer surface 11. (Gap 12G can have a thickness 12T and can be commonly indicated in the Figures.)

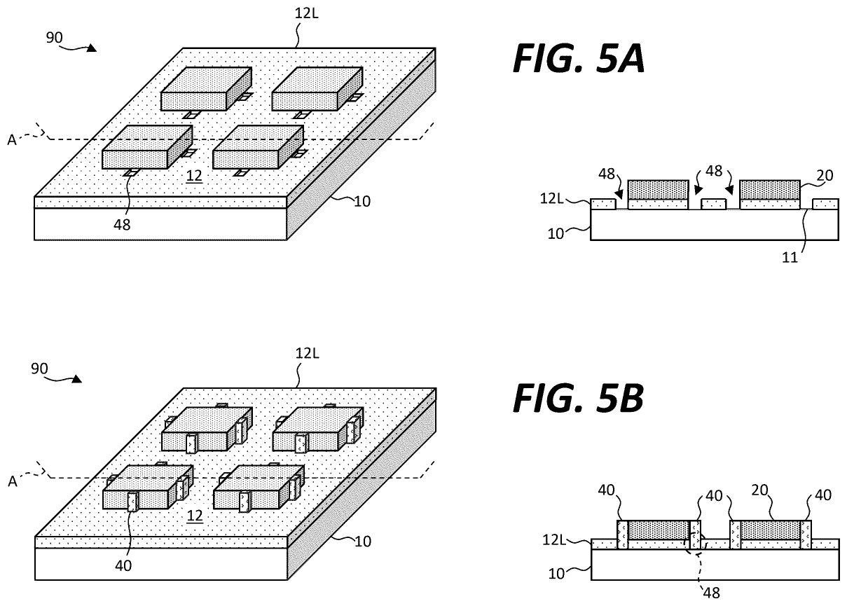

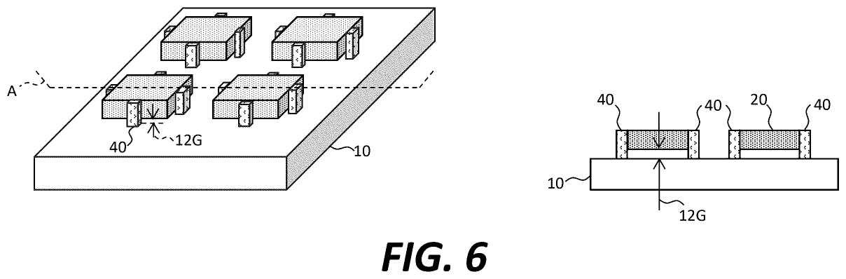

According to embodiments of the present disclosure and as shown in the successive structures of FIGS. 1A-1H and flow diagrams of FIGS. 7 and 8, a method of making a micro-transfer-printable component source structure 90 can comprise providing a source wafer 10 having a source-wafer surface 11 in step 100. As shown in FIG. 1A, a source wafer 10 can have a source-wafer surface 11. Source-wafer surface 11 can be substantially planar or at least locally planar within an area of the transfer-printable component source structure 90 and can form a horizontal surface H as opposed to a vertical direction V substantially orthogonal (or perpendicular) to horizontal surface H. As shown in FIG. 1B, a sacrificial layer 12L can be disposed on source-wafer surface 11. Sacrificial layer 12L can also be substantially planar and form a horizontal surface H and can comprise a material etchable with a liquid or gas such as TMAH, HCI or XeF₂.

Sacrificial layer 12L can be disposed on source-wafer surface 11 by known photolithographic methods such as sputtering, evaporation, or coating, such as spin or spray coating. In embodiments, an epitaxial layer (e.g., a semiconductor layer) can be disposed over sacrificial layer 12L, for example providing a semiconductor-on-insulator source wafer 10.

In embodiments of the present disclosure, sacrificial portions 12 (e.g., one or more portions of sacrificial layer 12L that are less than all of sacrificial layer 12L) and a component 20 can be formed over sacrificial layer 12L in steps 105 and 110. Sacrificial portion(s) 12 can be formed by pattern-wise etching sacrificial layer 12L using photolithographic methods and materials. Likewise, component 20 can be formed by photolithographically processing an epitaxial layer (not shown in FIGS. 1A-1H) using photolithographic methods and materials, for example forming an integrated circuit over source wafer 10 in step 110. Steps 105 and 110 can be performed in different orders, separately, or at least partially in common, according to some embodiments and as illustrated further in the FIG. 8 flow diagram. As shown in FIG. 8, a bulk substrate (e.g., source wafer 10) can be provided in step 200, sacrificial layer 12L disposed on the bulk substrate in step 205, and an epitaxial layer (e.g., a semiconductor layer) disposed on sacrificial layer 12L in step 210, for example as a semiconductor-on-insulator (SOI) structure as is known in the semiconductor arts and where the insulator can be a differentially etchable material from the epitaxial layer. In some embodiments and as shown in FIGS. 1C and 7, component 20 is formed in the epitaxial layer in steps 110 and 215 and the epitaxial layer patterned in step 220 to expose sacrificial layer 12L where components 20 are not present and then, as is shown in FIG. 1D, sacrificial layer 12L is patterned to form sacrificial portions 12 in step 225. (Steps 215, 220, and 225 can be one or more common steps or separate steps.) In some embodiments, the epitaxial layer is patterned either after or before component 20 is formed, as shown in FIG. 1C, and then sacrificial layer 12L is patterned to form sacrificial portions 12 where components 20 are not present. In both processes, a sacrificial portion 12 is disposed between each component 20 and source-wafer surface 11, as shown in FIG. 1D.

Each component 20 can be entirely, exclusively, and directly disposed on a sacrificial portion 12. Component 20 can comprise an etch-stop layer disposed between the epitaxial layer in which component 20 is formed and sacrificial portion 12 (not shown in the Figures), e.g., as a component bottom-side layer. Any etch-stop layer can be differentially etchable from sacrificial portion 12 or the epitaxial layer. Alternatively, or additionally, epitaxial layer (and component 20) can be differentially etchable from sacrificial portion 12.

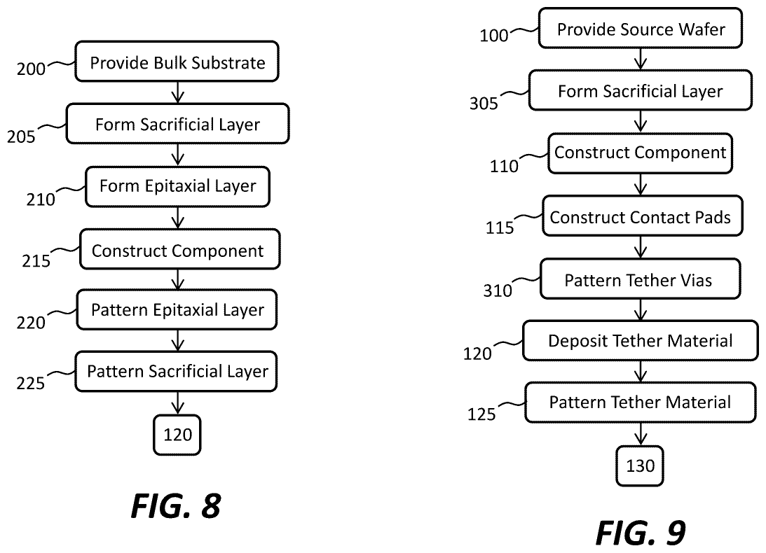

Component 20 can comprise a protective encapsulation layer 30 disposed over a top side of epitaxial layer in which component 20 on an opposite side of component 20 from source-wafer surface 11 and sacrificial portion 12, shown in FIG. 10, for example to protect component 20 structures and materials from an etchant used to etch sacrificial portion 12. A portion of encapsulation layer 30 present on component vertical side 20E can comprise vertical tether 40 so that a portion of vertical tether 40 encapsulates component vertical side 20E. In some embodiments, other structures useful for component 20, for example but not limited to contact pads 22, can be optionally formed in step 115, for example using photolithographic methods and materials.

In step 120 (FIG. 7), tether material can be deposited over source-wafer surface 11 in contact with source wafer 10 and at least a component vertical side 20E (e.g., a vertical side or edge) of component 20. The tether material can be in contact with a side (e.g. a vertical side or edge) or sacrificial-portion vertical side 12E of sacrificial portion 12 and can optionally extend over the top side of component 20. The tether material can comprise an organic or inorganic material, can be a resin, an epoxy, a photoresist, an oxide such as silicon dioxide, a nitride such as silicon nitride, a metal, a metal alloy, or combinations of these, for example in a multi-layer structure. The tether material can be substantially transparent or partially transparent.

The tether material can be differentially etchable from sacrificial portion 12 and can be deposited by photolithographic methods, such as sputtering, evaporation, or coating, such as spin or spray coating. By enabling such a variety of tether materials, embodiments of the present disclosure can be used in various integrated circuit fabrication assembly facilities having different process and material restrictions or limitations, for example depending on semiconductor materials processed in the facility.

As shown in FIG. 1E and FIG. 7, the tether material can be patterned in step 125 to form vertical tethers 40 using photolithographic methods such as etching through patterned masks defining vertical tethers 40. Vertical tether 40 can extend vertically from source-wafer surface 11 of source wafer 10 to component 20, for example in direct contact with component vertical side 20E (e.g., a component 20 side) and sacrificial-portion vertical side 12E (e.g., a sacrificial portion 12 side), physically connecting component 20 to source-wafer surface 11. In embodiments, component vertical sides 20E and sacrificial-portion vertical sides 12E can be at least partially or substantially vertical with respect to or orthogonal to source-wafer surface 11, subject to photolithographic manufacturing process tolerances and limitations. Vertical tether 40 can optionally extend over a top of component 20 and farther along source-wafer surface 11. The tether material can be deposited over source wafer 10 in a common step with other materials in component 20 and can have a thickness in a horizontal direction H in contact with component vertical side 20E that is substantially the same or less than a thickness of the same material deposited over component 20. For example, vertical tether 40 can comprise a same material as an encapsulation layer 30 of component 20 (e.g., a dielectric oxide or nitride) or can comprise a metal that is a same metal as is used in electrical conductors or contact pads 22 of or on component 20. Thus, in some embodiments, vertical tether 40 comprises a tether material, the tether material is also disposed on a top side of component 20 opposite source wafer 10, and a thickness of vertical tether 40 in the horizontal direction H is no greater than a thickness of the tether material disposed on the top side of component 20. The tether material disposed on the top side of component 20 can be patterned, for example to form useful structures in component 20, for example electrically conductive signal wires, insulating layers, and the like.

Vertical tether 40 can extend a horizontal tether distance 46 from component 20 to and along source-wafer surface 11 in a horizontal direction H orthogonal to sacrificial-portion vertical side 12E and parallel to source-wafer surface 11. Note that the direction of horizontal direction H orthogonal to sacrificial-portion vertical side 12E depends on the sacrificial-portion vertical side 12E (or component vertical side 20E) of component 20. Each vertical tether 40 (where multiple vertical tethers 40 are present) has a thickness in a horizontal direction H in a direction away from the sacrificial-portion vertical side 12E and component vertical side 20E in contact with vertical tether 40. In embodiments, sacrificial portion 12 (e.g., the patterned sacrificial layer 12L) extends no more than horizontal tether distance 46 beyond a component periphery 20P of component 20 surrounding component 20 in horizontal direction H. Such a vertical tether 40 structure and arrangement enables micro-transfer printing component 20 from source wafer 10 at an increased density of components 20 over source wafer 10, improving epitaxial and source wafer 10 material use and micro-transfer-printing yield, thereby reducing costs for micro-transfer-printed systems.

According to embodiments of the present disclosure, vertical tether 40 can be operable to break (e.g., fracture) in response to a stamp post 62 adhered to a top side of component 20 and pulling component 20 away from source-wafer surface 11, for example after sacrificial portion 12 is removed by etching the patterned sacrificial material. As shown in FIG. 1F, in step 130 of FIG. 7 sacrificial portion 12 can be etched to form a gap 12G between and separating component 20 and source-wafer surface 11 so that component 20 is suspended over source-wafer surface 11 by vertical tethers 40 (e.g., by one or more vertical tethers 40). In step 135 and as shown in FIG. 1G, component 20 can be contacted by a stamp 60, for example a stamp post 62 of stamp 60, to adhere stamp post 62 to component 20. Stamp 60 can be moved in a vertical direction V away from source wafer 10 to remove component 20 from source wafer 10 with stamp 60 and break (e.g., fracture) vertical tether 40 (or vertical tethers 40) to form broken (e.g., fractured) vertical tether 40F in step 140 and as shown in FIG. 1H. Stamp 60 can transport component 20 to a target (e.g., destination) substrate, for example using an optomechatronic transfer printer, in step 145 and printed to target substrate 50 in step 150. Stamp 60 can then be removed from target substrate 50 in step 155, leaving component 20 adhered to target substrate 50 and forming a micro-transfer-printed structure comprising component 20. Steps 130-155 can micro-transfer-print a component from source wafer 10 to target substrate 50 in multi-step 160.

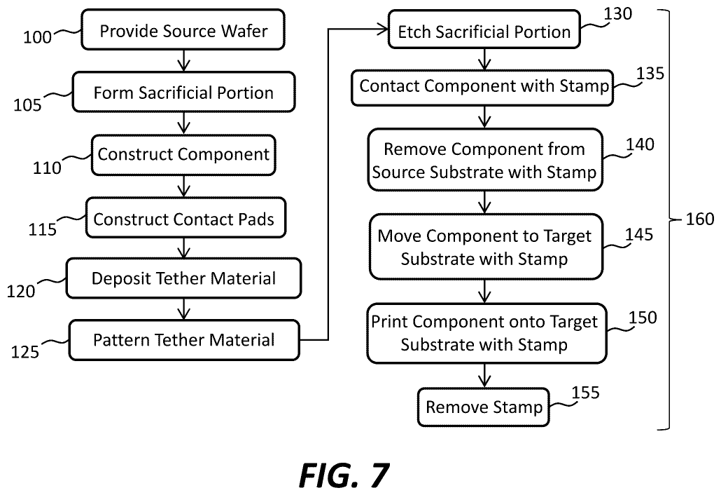

In some embodiments of the present disclosure, sacrificial layer 12L is not patterned to form sacrificial portions 12 (e.g., in step 105 or step 225) until after vertical tethers 40 are formed (e.g., in step 125). Instead, and as shown in FIGS. 5A-6, tether vias 48 are formed, vertical tethers 40 formed in tether vias 48, and sacrificial layer 12L is then patterned to form sacrificial portions 12. Thus, according to some embodiments of the present disclosure and as shown in the flow diagram of FIG. 9, a method of making a micro-transfer-printable component source structure 90 can comprise providing a source wafer 10 having a source-wafer surface 11 in step 100. A sacrificial layer 12L can be disposed on source-wafer surface 11 in step 305 (e.g., by coating, sputtering, or evaporation), and a component 20 disposed entirely on sacrificial layer 12L (e.g., by using photolithographic methods and materials, for example to construct an integrated circuit) in step 110. Optional contact pads 22 or other IC structures can be provided in step 115. Steps 100 and 305 can comprise providing a semiconductor-on-insulator source wafer 11.

In step 310 and as shown in FIG. 5A, methods of the present disclosure can comprise forming one or more tether vias 48 extending through sacrificial layer 12L to source-wafer surface 11 adjacent to component 20, for example closer to component 20 than another component 20. In step 120, tether material can be deposited, for example by coating, sputtering, or evaporation, over source wafer 10 and component 20. The deposited tether material can be patterned (e.g., photolithographically) in step 125 to form one or more vertical tethers 40 extending in an at least partially vertical direction V orthogonal to source-wafer surface 11 that physically connect component 20 to source-wafer surface 11 through each of the one or more tether vias 48, as shown in FIG. 5B. Each vertical tether 40 can extend along and in contact with a component vertical side 20E and sacrificial-portion vertical side 12E to physically connect component 20 to source-wafer surface 11. In embodiments, each vertical tether 40 can extend a horizontal tether distance 46 from component 20 along source-wafer surface 11 in a horizontal direction H at least partially orthogonal to sacrificial-portion vertical side 12E and parallel to source-wafer surface 11, for example directly away from and not along component vertical side 20E, component 20, and sacrificial-portion vertical side 12E, or sacrificial portion 12. In step 130 and as shown in FIG. 6, sacrificial layer 12L can be etched to form gap 12G separating component 20 from source-wafer surface 11 and suspending component 20 over source wafer 10. In such embodiments, sacrificial portions 12 need not be separately constructed. Steps 110-310 can be done in any useful order or can comprise common steps, for example tether vias 48 can be constructed in common steps with, before, or after, component 20 is formed in step 110 or optional contact pads 22 or other structures are formed in or on component 20.

Component 20 can be disposed over and on sacrificial portion 12 (e.g., in vertical direction V directly over and directly above sacrificial portion 12 and source-wafer surface 11) and can extend away from sacrificial portion 12 and source-wafer surface 11 in vertical direction V, so that component 20 is a substantially three-dimensional structure (e.g., has a volume). Component 20 can be directly and exclusively disposed over sacrificial portion 12 and can be in physical contact with sacrificial portion 12 so that every part of component 20 can be directly above and over (e.g., in vertical direction V) sacrificial portion 12. Component 20 can cover only a portion of sacrificial portion 12. Thus, sacrificial portion 12 can extend beyond component 20 so that not all of sacrificial portion 12 is covered by component 20 (as in FIG. 5B). In some embodiments, sacrificial portion 12 does not extend beyond component 20 so that all of sacrificial portion 12 is covered by component 20 (as in FIG. 1E), or sacrificial portion 12 does not extend beyond component 20 a distance greater than horizontal tether distance 46.

One or more edges of component 20 can be aligned with an edge of sacrificial portion 12. As used herein, an edge (e.g., of component 20 or sacrificial portion 12) is a side that extends at least partially orthogonally to sacrificial portion 12 (e.g., in a vertical direction V). An edge or side of component 20 or sacrificial portion 12 can be substantially vertical (e.g., substantially orthogonal to source-wafer surface 11) but, according to embodiments of the present disclosure, is at least not entirely horizontal so that the edge or side of component 20 or sacrificial portion 12 extends at least partially away from source-wafer surface 11, e.g., in vertical direction V, and can define a thickness of at least a portion of component 20 or sacrificial portion 12. Component vertical side 20E (e.g., component edge 20E) and sacrificial-portion vertical side 12E (e.g., sacrificial-portion vertical side 12E) can be in a common plane, can be in separate parallel planes, or can define separate planes.

Vertical tether 40 can be in physical contact (e.g., touching and in direct physical contact) with sacrificial-portion vertical side 12E of sacrificial portion 12. Vertical tether 40 can also be in contact with a horizontal side of sacrificial portion 12 that is opposite source-wafer surface 11, for example a substantially horizontal surface parallel to source-wafer surface 11 and on which component 20 is disposed.

In some embodiments, sacrificial portion 12 is differentially etchable from component 20 and can be horizontally accessible so that an etchant can be applied from above to sacrificial portion 12 to remove sacrificial material from sacrificial portion 12 to form a gap 12G having a sacrificial-portion thickness 12T between component 20 and source-wafer surface 11 of source wafer 10 and suspend component 20 over source-wafer surface 11 of source wafer 10 with vertical tether 40 attached to component 20.

According to embodiments of the present disclosure, vertical tethers 40 are specifically distinguished from micro-transfer printing tethers of the prior art because vertical tethers 40 have a vertical portion that at least partially extends vertically along an at least partially vertical side or sacrificial-portion vertical side 12E of sacrificial portion 12 from component 20 (e.g., from component vertical side 20E) to source-wafer surface 11. In embodiments, component vertical side 20E is at an edge or side of component 20 that extends in an at least partially vertical direction and is not a horizontal component bottom surface or a horizontal top surface of component 20. Component vertical side 20E can extend for a vertical distance that is a thickness of component 20 and along a width or length of component 20 substantially parallel to source-wafer surface 11 (e.g., in a horizontal direction).

In some embodiments of the present disclosure, the number of process steps can be reduced compared to methods of the prior art. For example, in some prior-art micro-transfer printing systems, a sacrificial layer must be disposed in a cavity, or an anchor structure must be built up over source-wafer surface 11, requiring additional process steps. In contrast, according to embodiments of the present disclosure, the entire vertical tether 40 can be constructed in a single series of photolithographic operations without requiring any process steps for forming a cavity. Thus, embodiments of the present disclosure can be simpler, faster, and easier to construct.

Source-wafer surface 11 can have an extensive, substantially planar area in two dimensions defining a horizontal surface H, for example a process side or process surface. A sacrificial portion 12 can be disposed on source wafer 10, for example on source-wafer surface 11 by patterning a sacrificial layer 12L. Sacrificial portion 12 can extend over only a portion of source-wafer surface 11 and has a sacrificial-portion vertical side 12E extending along a sacrificial-portion vertical side 12E of sacrificial portion 12 in a direction at least partially orthogonal to source-wafer surface 11. Thus, sacrificial portion 12 does not completely cover source-wafer surface 11. Source-wafer surface 11 can be considered a horizontal surface so that sacrificial-portion vertical side 12E extends at least partially in a vertical direction orthogonal to the horizontal source-wafer surface 11. (Horizontal and vertical are arbitrary designations of orthogonal dimensions or orthogonal directions.)

In some embodiments, an encapsulation layer 30 (that can comprise vertical tether 40) is deposited and patterned over or on (e.g., directly on or in direct physical contact with) one or more of source wafer 10 and source-wafer surface 11, for example over sacrificial-portion vertical side 12E, component vertical side 20E, and component 20 to form vertical tether 40. Where vertical tether 40 is disposed on component 20, vertical tether 40 can extend over and on component 20 at least partially in a horizontal direction parallel to source-wafer surface 11 and can at least partially encapsulate or electrically insulate component 20. Vertical tether 40 disposed over component 20 can encapsulate or cover some or all of component 20, for example some of component vertical side 20E. Where vertical tether 40 is disposed on at least a portion of component vertical side 20E (e.g., component edge 20E), vertical tether 40 can extend over and on component vertical side 20E in an at least partially vertical direction at least partially orthogonal to source-wafer surface 11 and can at least partially encapsulate or electrically insulate one or more component vertical sides 20E of component 20.

Where vertical tether 40 is disposed on sacrificial-portion vertical side 12E (e.g., sacrificial-portion vertical side 12E), vertical tether 40 can extend over and on sacrificial-portion vertical side 12E in a vertical direction at least partially orthogonal to source-wafer surface 11 and can be at least partially differentially etchable with respect to sacrificial portion 12. Where vertical tether 40 is disposed on sacrificial-portion vertical side 12E it can be patterned to have a width that is less than a width of component vertical side 20E or a portion of vertical tether 40 disposed on component vertical side 20E.

Vertical tether 40 can be an inorganic dielectric material such as silicon dioxide or silicon nitride or an organic material such as polyimide, resin, epoxy, a cured adhesive, or a photoresist, or layers of such materials. Vertical tether 40 material can be deposited and patterned using photolithographic techniques to pattern vertical tether 40, for example using material evaporation or sputtering followed by patterning with a masked photoresist and pattern-wise etching.

In general, when micro-transfer printing component 20 from source wafer 10, vertical tether 40 can break (e.g., fracture) along a break (e.g., fracture) line 42. Break (e.g., fracture) line 42 can take any shape but is illustrated as a straight line and can extend horizontally parallel to or on a diagonal (e.g., at least partly in vertical direction V) with respect to source-wafer surface 11, as shown with the multiple dashed lines in FIG. 10. Although multiple break (e.g., fracture) lines 42 are shown with dashed lines in FIG. 10, in actual practice only one break (e.g., fracture) line 42 is typically formed when removing component 20 from source wafer 10 with a stamp 60 after etching sacrificial material in sacrificial portion 12 to form gap 12G. Most often, break (e.g., fracture) lines 42 will extend from (e.g., begin or end at) some part of vertical tether 40 as shown in FIG. 10 where vertical tether 40 is disposed along sacrificial-portion vertical side 12E and is not along either source wafer 10 or component 20. In embodiments, in combination with tether neck 44, break (e.g., fracture) line 42 can form at a bottom of component 20 or top of sacrificial portion 12 or sacrificial layer 12L, as shown in FIGS. 2A, 2B.

Component 20 can be constructed using photolithographic processes to deposit, dope, and pattern one or more epitaxial layers of a semiconductor such as silicon or a compound semiconductor, to form any electrically or optically active structures (e.g., transistors, light emitting diodes, sensors, lasers, photodiodes, and the like), electrical connections, electrical circuits, optical structures, electro-optical structures, or contact pads 22 electrically connected to the structures or circuits. Component 20 can be a micro-device and can be an electrical, optical, or electro-optic component 20, for example an integrated circuit or photonic element such as a laser, for example a vertical-cavity surface-emission laser (VCSEL).

An inorganic encapsulation material such as silicon dioxide or silicon nitride or an organic material such as a polymer or photoresist, or multiple layers of such, can be deposited over component 20 and on at least a portion of source-wafer surface 11.

Patterned encapsulation material can form vertical tether 40, for example using photolithographic methods and materials. An encapsulation layer 30 can provide environmental and electrical insulation to component 20. Similarly, a patterned metal layer can be deposited over component 20 and on at least a portion of source-wafer surface 11 to form contact pads 22 or metal wires (electrical conductors) in or on component 20 and vertical tether 40, for example in common steps.

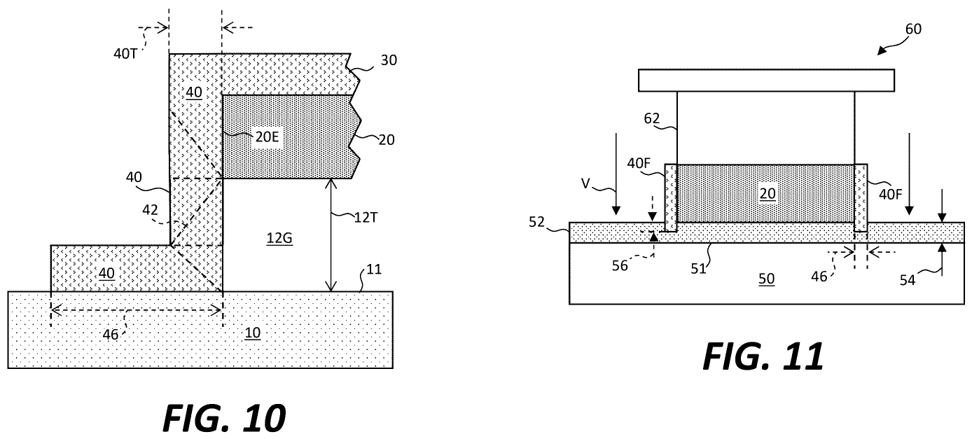

In some embodiments of the present disclosure, vertical tethers 40 can form a stand-off for component 20 from source wafer 10 and thereby prevent a bottom surface of component 20 from contacting source-wafer surface 11 and adhering to source-wafer surface 11 (for example with stiction) and inhibiting picking component 20 from source wafer 10 during micro-transfer printing. Vertical tethers 40 can break (e.g., fracture) as stamp 60 is moved away from source wafer 10 to remove component 20 from source wafer 10. In other embodiments as shown in FIG. 11, an adhesive layer 52 disposed on a target substrate 50 can accommodate (e.g., be thicker than) any portion of vertical tethers 40 that extends below component 20 (e.g., between component 20 and target substrate 50), enabling secure and robust positioning of component 20 on target substrate 50 when component 20 is micro-transfer printed from source wafer 10 to target substrate 50. Thus, as shown in FIG. 11, embodiments of the present disclosure can comprise a target substrate 50 having a target-substrate surface 51, an adhesive layer 52 having an adhesive-layer thickness 54 disposed on target-substrate surface 51, a component 20 disposed on adhesive layer 52 over target-substrate surface 51, and one or more vertical tethers 40 extending along a side of component 20 into adhesive layer 52 a vertical-tether distance 56 beyond a bottom side of component 20 adjacent to target substrate 50. Vertical-tether distance 56 can be no greater than adhesive-layer thickness 54.

If a vertical tether standoff (a remnant of broken (e.g., fractured) vertical tether 40F) is present and attached to component 20, the vertical tether standoff can press into liquid adhesive layer 52 (if present) so that a component bottom surface can be disposed substantially parallel to target-substrate surface 51 of target substrate 50 and can completely contact adhesive layer 52, for example as desired, to adhere component 20 to target-substrate surface 51. In the absence of adhesive layer 52 and in the presence of a broken (e.g., fractured) vertical tether 40F standoff, component bottom surface could be prevented from closely contacting target-substrate surface 51 and thereby be prevented from adequately adhering to target-substrate surface 51.

Target substrate 50 can be coated (e.g., by spin or spray coating) with an uncured and liquid adhesive layer 52 before component 20 is pressed against target substrate 50 in step 150 so that component 20 is printed to adhesive layer 52 on target substrate 50. Adhesive layer 52 can then be cured. Adhesive layer 52 can be a polymer, for example a curable epoxy, resin, or photoresist that can be cured, for example by UV radiation exposure or heat.

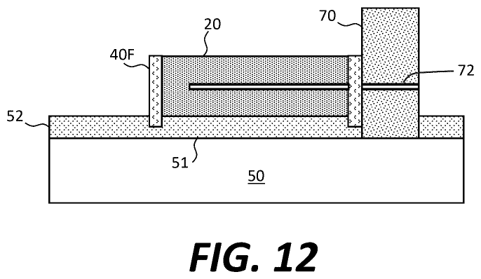

By using vertical tethers 40, the horizontal extent of micro-transfer-printed components 20 is reduced and component vertical side 20E or vertical tether 40 can come into direct contact with mechanical structures 70 on a target substrate 50, depending on the thickness and location of vertical tethers 40 and the location of the mechanical structure 70, improving alignment or proximity between component 20 with the target substrate mechanical structures 70, as shown in FIG. 12. Where component 20 is a photonic device, light exiting or entering component 20 can pass through vertical tether 40, or not, depending on the configuration of component 20, for example pass light into or out of mechanical structure 70. Mechanical structure 70 can, for example, comprise a wave guide 72 or light pipe for conveying light in a photonic system comprising component 20. Vertical tether 40 can be substantially transparent, for example 50%, 60%, 70%, 80%, 90% or 95% transparent to light that passes through wave guide 72 to or from component 20.

In general, depositing and patterning materials and forming structures can be done with conventional photolithographic methods and materials, for example by coating with a photoresist, pattern-wise exposing and developing the photoresist, etching the patterned photoresist, and stripping the photoresist to make a patterned layer. The different layers and structures formed on the process side (source-wafer surface 11 of source wafer 10) can be patterned in separate steps with different etchants and can be patterned into the same pattern or different patterns. Components 20 can be formed on source-wafer surface 11 using photolithographic process and materials. In step 110 one or more dielectric or electrically conductive layers (e.g., including any combination of metal or silicon dioxide, patterned conductors, electrodes, or encapsulation layers 30) can be disposed and patterned on source wafer 10 and sacrificial portion 12 to form component 20 with any electronic or photonic circuits.

In embodiments of the present disclosure, component 20 is or comprises an integrated circuit, a digital circuit, a CMOS circuit, a diode, transistor, a photonic structure, a laser, a light-emitting diode, a sensor, a light modulator, a light amplifier, or a photodiode. Component 20 can have a length or width less than or equal to two hundred microns, less than or equal to one hundred microns, less than or equal to fifty microns, less than or equal to twenty microns, less than or equal to ten microns, less than or equal to five microns, or less than or equal to two microns. Component 20 can have a thickness or depth less than or equal to ten nm, twenty nm, fifty nm, one hundred nm, one micron, two microns, five microns, ten microns, twenty microns, or fifty microns. Component 20 can have a length or width less than or equal to two nm, less than or equal to five nm, less than or equal to ten nm, less than or equal to twenty nm, less than or equal to fifty nm, or less than or equal to one hundred nm.

Methods of forming micro-transfer printable structures are described, for example, in the paper AMOLED Displays using Transfer-Printed Integrated Circuits (Journal of the Society for Information Display, 2011, DOI #10.1889/JSID19.4.335, 1071-0922/11/1904-0335, pages 335-341) and U.S. Pat. No. 8,889,485, referenced above. For a discussion of micro-transfer printing techniques see, U.S. Pat. Nos. 8,722,458, 7,622,367 and 8,506,867, each of which is hereby incorporated by reference in its entirety. Micro-transfer printing using compound micro-assembly structures and methods can also be used with the present disclosure, for example, as described in U.S. patent application Ser. No. 14/822,868, filed Aug. 10, 2015, entitled Compound Micro-Assembly Strategies and Devices, which is hereby incorporated by reference in its entirety. Additional details useful in understanding and performing aspects of the present disclosure are described in U.S. patent application Ser. No. 14/743,981, filed Jun. 18, 2015, entitled Micro Assembled LED Displays and Lighting Elements, which is hereby incorporated by reference in its entirety.

Reference is made throughout the present description to examples of printing that are micro-transfer printing with stamp 60 comprising stamp post 62 when describing certain examples of printing components 20. Similar other embodiments are expressly contemplated where a transfer element 60 that is not a stamp is used to similarly print components 20. For example, in some embodiments, a transfer element 60 that is a vacuum-based, magnetic, or electrostatic transfer element 60 can be used to print components 20. A component 20 can be adhered to a transfer element 60 with any type of force sufficient to maintain contact between the component 20 and transfer element 60 when desired and separate transfer element 60 from component 20 when desired. For example, component 20 can be adhered to transfer element 60 with one or more of an adhesion, electrostatic, van der Waals, magnetic, or vacuum force. In some embodiments, adhesion between component 20 and transfer element 60 occurs at least in part due to a force generated by operating transfer element 60 (e.g., an electrostatic force) and separation of transfer element 60 from component 20 occurs at least in part by ceasing provision of the force (e.g., an electrostatic force). A vacuum-based, magnetic, or electrostatic transfer element 60 can comprise a plurality of transfer posts, each transfer post being constructed and arranged to pick up a single component 20 (similarly to stamp posts 62 in stamp 60).

As is understood by those skilled in the art, the terms “over” and “under” and “vertical” and “horizontal” are relative terms and can be interchanged in reference to different orientations of the layers, elements, and substrates included in the present disclosure. For example, a first layer on a second layer, in some implementations means a first layer directly on and in contact with a second layer. In other implementations, a first layer on a second layer includes a first layer and a second layer with another layer therebetween.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the disclosure.

### PARTS LIST

A cross-section line
H horizontal plane
V vertical direction
W1 component separation
W2 twice horizontal tether distance
10 source wafer/source substrate
11 source-wafer surface
12 sacrificial portion
12E sacrificial-portion vertical side/sacrificial-portion vertical side
12G gap
12L sacrificial layer
12T gap thickness/sacrificial-layer thickness
20 component
20E component edge/component vertical side
20P component periphery
22 contact pad
30 encapsulation layer
40 vertical tether
40F broken (e.g., fractured) vertical tether
40T tether thickness
40W tether width
42 break (e.g., fracture) line/tether break (e.g., fracture) location
44 tether neck/minimum width/minimum thickness
46 horizontal tether distance
48 tether via
50 target substrate
51 target-substrate surface
52 adhesive layer
54 adhesive-layer thickness
56 vertical-tether distance
60 stamp/transfer element
62 stamp post
70 mechanical structure
72 waveguide
90 micro-transfer-printable component source structure
100 provide source wafer step
105 form sacrificial portion step
110 construct component step
115 construct contact pads step
120 deposit tether material step
125 pattern tether material step
130 etch sacrificial portion step
135 contact component with stamp step
140 remove component from substrate with stamp step
145 move component to target substrate with stamp step
150 print component onto target substrate with stamp step
155 remove stamp step
160 micro-transfer-print electronic circuit from source wafer to target substrate step
200 provide bulk substrate step
205 form sacrificial layer step
210 form epitaxial layer step
215 construct component step
220 pattern epitaxial layer step
225 pattern sacrificial layer step
305 form sacrificial layer step
310 pattern tether vias step

1. A micro-transfer-printable component source structure, comprising:
a source wafer having a source-wafer surface;
a patterned sacrificial layer comprising a sacrificial material disposed on only a portion of the source-wafer surface forming a sacrificial portion;
a component disposed on and entirely over the sacrificial portion; and
a vertical tether extending in an at least partially vertical direction orthogonal to the source-wafer surface along a sacrificial-portion vertical side of the sacrificial portion to the component,
wherein (i) the vertical tether physically connects the component to the source-wafer surface, (ii) the vertical tether extends a horizontal tether distance from the component along the source-wafer surface in a horizontal direction directly away from the sacrificial-portion vertical side and parallel to the source-wafer surface, and (iii) the sacrificial portion extends no more than the horizontal tether distance beyond a component periphery surrounding the component in the horizontal direction.

2. The micro-transfer-printable component source structure of claim 1, wherein the component comprises a component vertical side that extends along the component at least partially in the vertical direction and the vertical tether extends at least partially along and in contact with the component vertical side.

3. The micro-transfer-printable component source structure of claim 1, wherein the vertical tether extends onto a component top side of the component opposite the source-wafer surface.

4. The micro-transfer-printable component source structure of claim 1, wherein the vertical tether is constructed to break in response to a stamp post adhered to a component top side of the component opposite the source-wafer surface pulling the component away from the source-wafer surface.

5. The micro-transfer-printable component source structure of claim 1, comprising one or multiple vertical tethers extending at least partially in the vertical direction from the source-wafer surface along at least a portion of one or more sacrificial-portion vertical sides of the sacrificial portion to the component, and physically connecting the component to the source-wafer surface.

6. The micro-transfer-printable component source structure of claim 5, wherein the component periphery comprises multiple component vertical sides together defining a polygon, each component vertical side extending at least partially in the vertical direction, and a vertical tether of the multiple vertical tethers is disposed along each component vertical side of the multiple component vertical sides.

7. The micro-transfer-printable component source structure of claim 1, wherein the horizontal tether distance is less than a thickness of the component and/or less than a thickness of the patterned sacrificial layer in the vertical direction.

8. The micro-transfer-printable component source structure of claim 1, wherein the vertical tether has a variable tether width in a direction orthogonal to the horizontal direction and parallel to the source-wafer surface.

9. The micro-transfer-printable component source structure of claim 8, wherein the variable tether width has a minimum width adjacent to the sacrificial portion in the horizontal direction.

10. The micro-transfer-printable component source structure of claim 9, wherein the minimum width is disposed substantially at a sacrificial-portion top side of the sacrificial portion opposite and substantially parallel to the source-wafer surface.

11. The micro-transfer-printable component source structure of claim 1, wherein the vertical tether has a variable tether thickness in a direction parallel to the horizontal direction.

12. The micro-transfer-printable component source structure of claim 11, wherein the variable tether thickness has a minimum thickness adjacent to the sacrificial portion in the horizontal direction.

13. The micro-transfer-printable component source structure of claim 12, wherein the minimum thickness is disposed substantially at a sacrificial-portion top side of the sacrificial portion opposite the source-wafer surface.

14. The micro-transfer-printable component source structure of claim 1, wherein the vertical tether comprises a tether material, the tether material is also disposed on a component top side of the component opposite the source wafer, and a thickness of the vertical tether in the horizontal direction is no greater than a thickness of the tether material disposed on the component top side.

15. A micro-transfer-printable component source structure, comprising:
a source wafer having a source-wafer surface;
a patterned sacrificial layer comprising a sacrificial material disposed on only a portion of the source-wafer surface forming multiple separate sacrificial portions; and
for each of the sacrificial portions:
a respective component disposed on and entirely over the sacrificial portion, and
a respective vertical tether extending in an at least partially vertical direction orthogonal to the source-wafer surface along a sacrificial-portion vertical side of the sacrificial portion to the respective component,
wherein (i) the respective vertical tether physically connects the respective component to the source-wafer surface, (ii) the respective vertical tether extends a horizontal tether distance from the component to the source-wafer surface in a horizontal direction directly away from the sacrificial-portion vertical side and parallel to the source-wafer surface, (iii) the sacrificial portion extends no more than the horizontal tether distance beyond a component periphery surrounding the respective component in a direction parallel to the source-wafer surface,
wherein a distance in the horizontal direction between adjacent components is no greater than twice the horizontal tether distance.

16. A micro-transfer-printable component source structure, comprising:
a source wafer having a source-wafer surface;
a sacrificial layer comprising a sacrificial material disposed on the source-wafer surface, the sacrificial layer comprising one or more tether vias extending through the sacrificial layer to the source-wafer surface;
a component disposed on and entirely over the sacrificial layer; and
a vertical tether extending away from the source-wafer surface to the component through each of the one or more tether vias, wherein each vertical tether physically connects the component to the source-wafer surface.

17. The micro-transfer-printable component source structure of claim 16, comprising multiple components disposed on the sacrificial layer and wherein the vertical tether extends a horizontal tether distance from the component along the source-wafer surface in a horizontal direction directly away from the sacrificial-portion vertical side and parallel to the source-wafer surface and the distance between adjacent ones of the multiple components is no greater than twice the horizontal tether distance.

18. A micro-transfer-printable component source structure, comprising:
a source wafer having a source-wafer surface;
a component disposed over the source-wafer surface; and
one or more vertical tethers extending away from the source-wafer surface to the component, wherein each vertical tether physically connects the component to the source-wafer surface such that a gap separates the component from the source-wafer surface,
wherein the one or more vertical tethers suspend the component over the source-wafer surface.

19. A micro-transfer-printable component target structure, comprising:
a target substrate having a target-substrate surface;
an adhesive layer having an adhesive-layer thickness disposed on the target substrate surface;
a component disposed on the adhesive layer; and
one or more vertical tethers extending into the adhesive layer beyond a component bottom side of the component by a vertical-tether distance, wherein the vertical-tether distance is no greater than the adhesive layer thickness.

20. The micro-transfer-printable component target structure of claim 19, comprising a mechanical structure disposed on the target substrate, wherein a component vertical side of the component extending at least partially orthogonal to the target substrate is in contact with the mechanical structure or at least one of the one or more vertical tethers is in contact with the mechanical structure.

21-26. (canceled)
